(19) United States
(12) Patent Application Publication
(10) Pub. No.: US 2016/0209943 A1
(43) Pub. Date: Jul. 21, 2016

(54) TRANSPARENT CONDUCTIVE STRUCTURE HAVING METAL MESH

(71) Applicants: Interface Optoelectronics (ShenZhen) Co., Ltd., Shenzhen (CN); General Interface Solution Limited, Miaoli County (TW)

(72) Inventors: Jing-Bing YU, Guangdong (CN); Tai-Wu LIN, Guangdong (CN)

(21) Appl. No.: 14/810,486

(22) Filed: Jul. 28, 2015

(30) Foreign Application Priority Data
Jan. 21, 2015 (CN) 201510031356.6

(51) Int. Cl. G06F 3/041; H05K 1/02

(52) U.S. Cl. CPC G06F 3/041; H05K 1/0296; H05K 1/0274; G06F 2203/04112; G06F 2203/04107

(57) ABSTRACT

The present disclosure provides a transparent conductive structure having metal mesh and including a transparent substrate, a first metal mesh structure, a first transparent insulating layer, a second metal mesh structure and a second transparent insulating layer. The transparent substrate has a top surface and a bottom surface opposite to the top surface. The first metal mesh structure is disposed on the top surface of the transparent substrate. The first transparent insulating layer surrounds the first metal mesh structure, and covers the top surface of the transparent substrate. The second metal mesh structure is disposed on the bottom surface of the transparent substrate. The second transparent insulating layer surrounds the second metal mesh structure, and covers the bottom surface of the transparent substrate.

### RELATED APPLICATIONS

This application claims priority to Chinese Application Serial Number 201510031356.6, filed Jan. 21, 2015, which is herein incorporated by reference.

### BACKGROUND

1. Field of Invention

The present invention relates to a transparent conductive structure having metal mesh. More particularly, the present invention relates to a transparent conductive structure having transparent insulating layer isolated from surrounding vapor to avoid vapor contact with the first and second metal mesh structures.

2. Description of Related Art

In the past, a typical touch panel generally uses indium tin oxide (ITO) as transparent conductive material. However, the sheet resistance value (150-400 Ω/□) and linear resistance value (10,000-50,000 Ω/□) of ITO are higher than that of metal. The total surface resistance of the touch panel increases with the increasing area of touch panel, so as to lower the response speed and sensitivity of the touch panel. Therefore, the traditional ITO touch panel is gradually replaced with that having metal mesh made of sliver (Ag) as conductive material.

Although Ag has a very small resistance value, Ag is relatively chemically reactive so that Ag is apt to react with surrounding vapor to become Ag ions. The Ag ions migrate and lead to short circuit between neighboring conductive wires, which fails the electricity of the touch panel.

In this regard, there is a need for a new transparent conductive structure to solve the deficiencies of traditional transparent conductive structure.

### SUMMARY

In order to solve the phenomenon of Ag ionic migration caused by traditional transparent conductive structure. The embodiments of present disclosure provide a transparent conductive structure to solve the problems of traditional transparent conductive structure since long ago.

One aspect of the present disclosure provides a transparent conductive structure, which includes a transparent substrate, a first metal mesh structure, a first transparent insulating layer, a second metal mesh structure and a second transparent insulating layer.

The transparent substrate has a top surface and a bottom surface opposite to the top surface. The first metal mesh structure is disposed on the top surface of the transparent substrate. The first transparent insulating layer surrounds the first metal mesh structure, and covers the top surface of the transparent substrate. The second metal mesh structure is disposed on the bottom surface of the transparent substrate. The second transparent insulating layer surrounds the second metal mesh structure, and covers the bottom surface of the transparent substrate.

### BRIEF DESCRIPTION OF THE DRAWINGS

The invention can be more fully understood by reading the following detailed description of the embodiment, with reference made to the accompanying drawings as follows:

FIG. 1A schematically shows a top view of a transparent conductive structure 100 according to the embodiments of the present disclosure;

FIG. 1B schematically shows a cross-sectional view of a transparent conductive structure 100 along A-A′ profile line according to the embodiments of the present disclosure;

FIG. 2 schematically shows a cross-sectional view of a transparent conductive structure 200 according to the embodiments of the present disclosure;

FIG. 3A schematically shows a top view of a transparent conductive structure 300 according to the embodiments of the present disclosure;

FIG. 3B schematically shows a cross-sectional view of a transparent conductive structure 300 along B-B′ profile line according to the embodiments of the present disclosure; and

FIG. 4 schematically shows a cross-sectional view of a transparent conductive structure 400 according to the embodiments of the present disclosure.

### DETAILED DESCRIPTION

The following embodiments are disclosed with accompanying diagrams for detailed description. For illustration clarity, many details of practice are explained in the following descriptions. However, it should be understood that these details of practice do not intend to limit the present invention. That is, these details of practice are not necessary in parts of embodiments of the present invention. Furthermore, for simplifying the drawings, some of the conventional structures and elements are shown with schematic illustrations. In fact, the dimensions of the various features may be arbitrarily increased or reduced for clarity of discussion.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising”, or “includes” and/or “including” or “has” and/or “having” when used in this specification, specify the presence of stated features, regions, integers, steps, operations, elements, and/or components, but do not preclude the presence or addition of one or more other features, regions, integers, steps, operations, elements, components, and/or groups thereof. Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

In order to solve the phenomenon of Ag ionic migration caused by traditional transparent conductive structure. The embodiments of present disclosure provide a transparent conductive structure having a transparent insulating layer surrounding the metal mesh structures. The surrounding water may be isolated from the transparent conductive structure so that the water avoids contact with the metal mesh structures. That may solves the problems of transparent conductive structure having metal mesh since long ago.

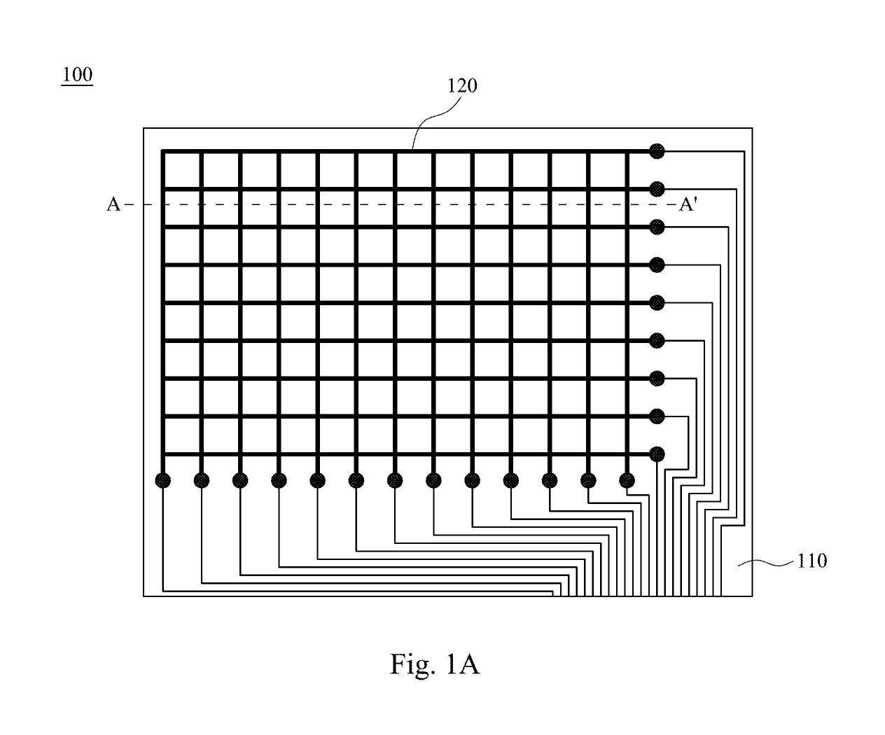

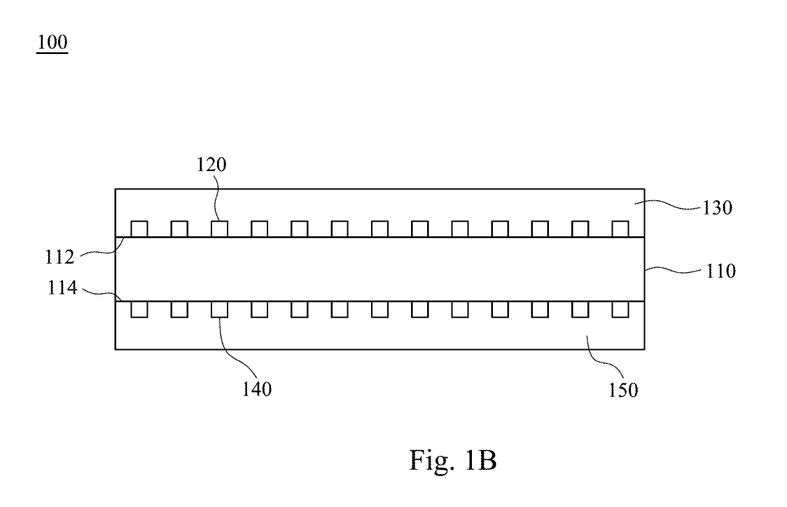

FIG. 1A schematically shows a top view of a transparent conductive structure 100 according to the embodiments of the present disclosure. In FIG. 1A, transparent conductive structure 100 includes a transparent substrate 110 and a first metal mesh structure 120.

Then, referring to FIG. 1B, FIG. 1B schematically shows a cross-sectional view of a transparent conductive structure 100 along A-A′ profile line according to the embodiments of the present disclosure. In FIG. 1B, transparent conductive structure 100 includes a transparent substrate 110, a first metal mesh structure 120, a first transparent insulating layer 130, a second metal mesh structure 140 and a second transparent insulating layer 150.

The transparent substrate 110 has a top surface 112 and a bottom surface 114 opposite to the top surface 112. According to embodiments of the disclosure, the transparent substrate 110 is rigid substrate or flexible substrate. According to embodiments of the disclosure, rigid substrate includes glass, glass fiber, or hard plastics. According to embodiments of the disclosure, flexible substrate includes polyethylene (PE), polyethylene terephthalate (PET), tri-cellulose Acetate (TCA) or a combination thereof. According to embodiments of the disclosure, the thickness of transparent substrate 110 is 50-125 micrometer (μm).

The first metal mesh structure 120 is disposed on the top surface 112 of the transparent substrate 110. According to embodiments of the disclosure, the material of first metal mesh structure 120 is copper (Cu), Ag, or a combination thereof. According to embodiments of the disclosure, the thickness of first metal mesh structure 120 is 0.8-1.2 μm.

In one embodiment of the disclosure, the step of forming the first metal mesh structure 120 includes forming a first metal layer and patterning the first metal layer. First, form the first metal layer on the top surface 112 of the transparent substrate 110. In one embodiment of the disclosure, the method of forming the first metal layer includes physical vapor deposition (PVD) or chemical vapor deposition (CVD).

Then, pattern the first metal layer by lithography process to form the first metal mesh structure 120. In one embodiment of the disclosure, the method of patterning the first metal layer includes dry etching or wet etching.

The first transparent insulating layer 130 surrounds the first metal mesh structure 120 and covers the top surface 112 of the transparent substrate 110. According to embodiment of the disclosure, the material of first transparent insulating layer 130 is optical clear adhesive (OCA). According to embodiments of the disclosure, the optical clear adhesive is transparent acrylic adhesive. According to embodiments of the disclosure, the thickness of first transparent insulating layer 130 is 50-300 μm, preferably 50125 μm.

In one embodiment of the disclosure, the method of forming the first transparent insulating layer 130 includes coating a transparent insulating material directly on the first metal mesh structure 120 and the top surface 112 which has contact with transparent substrate 110. In this embodiment, the transparent insulating material surrounds the first metal mesh structure 120 and covers the top surface 112 of transparent substrate 110 so that there exists no any other structure or gap between the first transparent insulating layer 130, the first metal mesh structure 120 and the top surface 112 of transparent substrate 110. Therefore, the surrounding water cannot permeate or penetrate through the first transparent insulating layer 130 and cannot react with the first metal mesh structure 120 to generate Ag ionic migration.

The second metal mesh structure 140 is disposed on the bottom surface 114 of the transparent substrate 110. According to embodiments of the disclosure, the material of second metal mesh structure 140 is Cu, Ag, or a combination thereof. According to embodiments of the disclosure, the thickness of second metal mesh structure 140 is 0.8-1.2 μm.

In one embodiment of the disclosure, the step of forming the second metal mesh structure 140 includes forming a second metal layer and patterning the second metal layer. First, form the second metal layer on the bottom surface 114 of the transparent substrate 110. In one embodiment of the disclosure, the method of forming the second metal layer includes physical vapor deposition (PVD) or chemical vapor deposition (CVD).

Then, pattern the second metal layer by lithography process to form the second metal mesh structure 140. In one embodiment of the disclosure, the method of patterning the second metal layer includes dry etching or wet etching.

The second transparent insulating layer 150 surrounds the second metal mesh structure 140 and covers the bottom surface 114 of the transparent substrate 110. According to embodiment of the disclosure, the material of second transparent insulating layer 150 is optical clear adhesive. According to embodiments of the disclosure, the optical clear adhesive is transparent acrylic adhesive. According to embodiments of the disclosure, the thickness of second transparent insulating layer 150 is 50-300 μm, preferably 100-300 μm.

In one embodiment of the disclosure, the method of forming the second transparent insulating layer 150 includes coating a transparent insulating material directly on the second metal mesh structure 140 and the bottom surface 114 which has contact with transparent substrate 110. In this embodiment, the transparent insulating material surrounds the second metal mesh structure 140 and covers the bottom surface 114 of transparent substrate 110 so that there exists no any other structure or gap between the second transparent insulating layer 150, the second metal mesh structure 140 and the bottom surface 114 of transparent substrate 110. Therefore, the surrounding water cannot permeate or penetrate through the first transparent insulating layer 150 and cannot react with the second metal mesh structure 140 to generate Ag ionic migration.

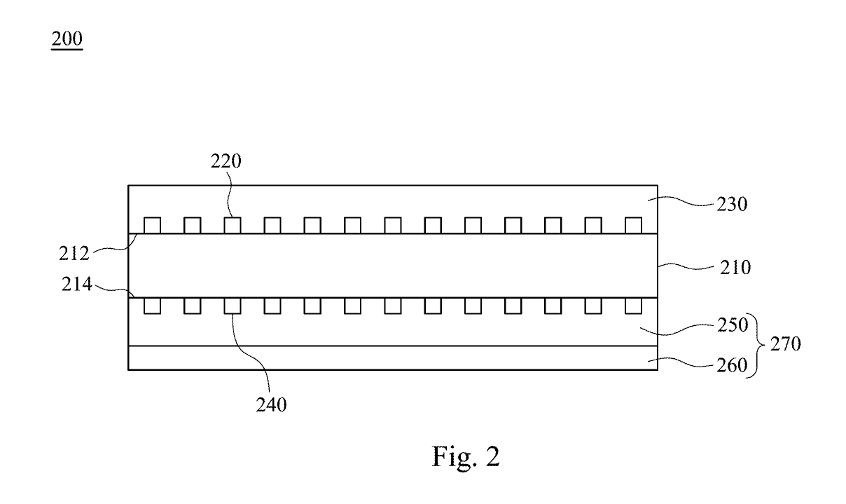

FIG. 2 schematically shows a cross-sectional view of a transparent conductive structure 200 according to the embodiments of the present disclosure. In FIG. 2, the transparent conductive structure 200 includes a transparent substrate 210, a first metal mesh structure 220, a first transparent insulating layer 230, a second metal mesh structure 240, a second transparent insulating layer 250 and a transparent protective layer 260.

The transparent substrate 210 has a top surface 212 and a bottom surface 214 opposite to the top surface 112. According to embodiments of the disclosure, the materials and thickness of transparent substrate 210 are same as transparent substrate 110 in FIG. 1B.

The first metal mesh structure 220 is disposed on the top surface 212 of the transparent substrate 210. According to embodiments of the disclosure, the materials and thickness of first metal mesh structure 220 are same as first metal mesh structure 120 in FIG. 1B.

According to embodiments of the disclosure, the method of forming the first metal mesh structure 220 in FIG. 2 is same as the method of forming the first metal mesh structure 120 in FIG. 1B. There is no need to give unnecessary details.

The first transparent insulating layer 230 surrounds the first metal mesh structure 220 and covers the top surface 212 of the transparent substrate 210. According to embodiment of the disclosure, the materials and thickness of first transparent insulating layer 230 are same as the first transparent insulating layer 130 in FIG. 1B. According to embodiment of the disclosure, the method of forming the first transparent insulating layer 230 in FIG. 2 is same as the method of forming the first transparent insulating layer 130 in FIG. 1B. There is no need to give unnecessary details.

According to embodiment of the disclosure, the first transparent insulating layer 230 further includes a cover sheet (not shown) on the first transparent insulating layer 230. The material of cover sheet may be glass or plastics.

The second metal mesh structure 240 is disposed on the bottom surface 214 of the transparent substrate 210. According to embodiments of the disclosure, the materials and thickness of second metal mesh structure 240 are same as the second metal mesh structure 140 in FIG. 1B.

According to embodiments of the disclosure, the method of forming the second metal mesh structure 240 in FIG. 2 is same as the method of forming the second metal mesh structure 140 in FIG. 1B. There is no need to give unnecessary details.

The second transparent insulating layer 250 surrounds the second metal mesh structure 240 and covers the bottom surface 214 of the transparent substrate 210. According to embodiment of the disclosure, the materials and thickness of second transparent insulating layer 250 are same as the second transparent insulating layer 150 in FIG. 1B. According to embodiments of the disclosure, the method of forming the second transparent insulating layer 250 in FIG. 2 is same as the method of forming the transparent insulating layer 150 in FIG. 1B. There is no need to give unnecessary details.

The transparent protective layer 260 covers the second transparent insulating layer 250. In one embodiment of the disclosure, the second transparent insulating layer 250 and the transparent protective layer 260 constitute an anti-scattering film 270. According to embodiments of the disclosure, the transparent protective layer 260 includes polyethylene (PE), polyethylene terephthalate (PET), tri-cellulose Acetate (TCA) or a combination thereof. According to embodiments of the disclosure, the thickness of transparent protective layer 260 is 50-125 micrometer (m).

In one embodiment of the disclosure, after the second transparent insulating layer 250 forms on the second metal mesh structure 240 and the bottom surface 214 of transparent substrate 210, the transparent protective layer 260 adheres on the second transparent insulating layer 250. In another embodiment of the disclosure, after the second transparent insulating layer 250 and the transparent protective layer 260 constitute the anti-scattering film 270, the anti-scattering film 270 adheres on the second metal mesh structure 240 and the bottom surface 214 of transparent substrate 210. Because the transparent protective layer 260 is composed of macromolecules, the transparent protective layer 260 and the second transparent insulating layer 250 can constitute the anti-scattering film 270 and increase the safety of transparent conductive structure 200.

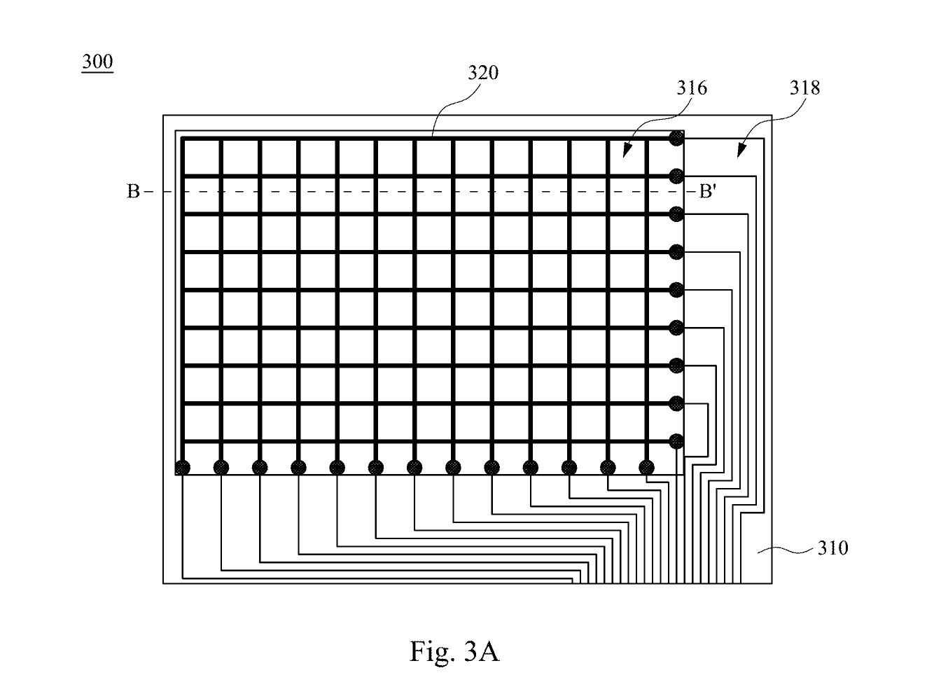

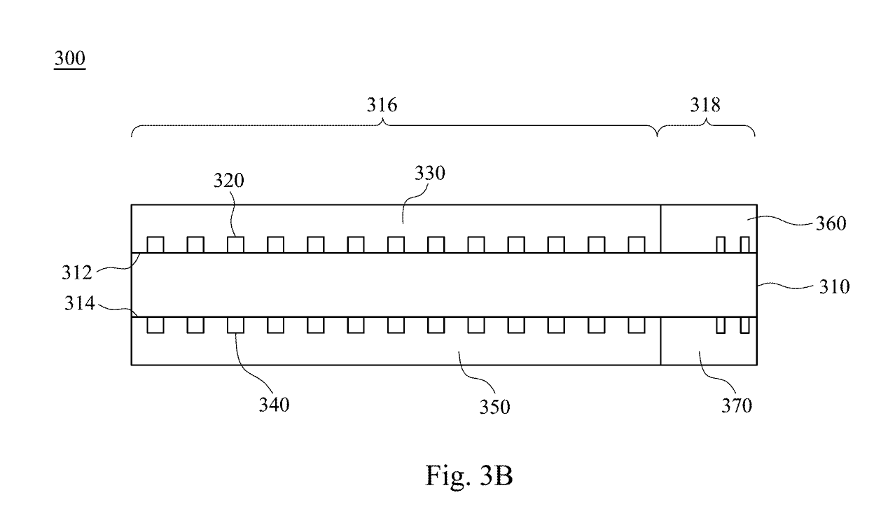

FIG. 3A schematically shows a top view of a transparent conductive structure 300 according to the embodiments of the present disclosure. In FIG. 3A, the transparent conductive structure 300 includes a transparent substrate 310 and a first metal mesh structure 320. The transparent substrate 310 has a first region 316 and a second region 318 next to the first region 316. The first metal mesh structure 320 mainly positions on the first region 316 of transparent substrate 310.

Then, referring to FIG. 3B, FIG. 3B schematically shows a cross-sectional view of a transparent conductive structure 300 along B-B′ profile line according to the embodiments of the present disclosure. In FIG. 3B, the transparent conductive structure 300 includes a transparent substrate 310, a first metal mesh structure 320, a first transparent insulating layer 330, a second metal mesh structure 340, a second transparent insulating layer 350, a first opaque insulating layer 360 and a second opaque insulating layer 370.

The transparent substrate 310 has a top surface 312 and a bottom surface 314 opposite to the top surface 312. According to embodiments of the disclosure, the materials and thickness of transparent substrate 310 are same as transparent substrate 110 in FIG. 1B.

The first metal mesh structure 320 is disposed on the top surface 312 of the first region 316 of the transparent substrate 310. According to embodiments of the disclosure, the materials and thickness of first metal mesh structure 320 are same as first metal mesh structure 120 in FIG. 1B.

According to embodiments of the disclosure, the method of forming the first metal mesh structure 320 in FIG. 3B is same as the method of forming the first metal mesh structure 120 in FIG. 1B. There is no need to give unnecessary details.

The first transparent insulating layer 330 surrounds the first metal mesh structure 320 and covers the top surface 312 of the first region 316 of the transparent substrate 310. According to embodiment of the disclosure, the materials and thickness of first transparent insulating layer 330 are same as the first transparent insulating layer 130 in FIG. 1B. In one embodiment of the disclosure, the method of forming the first transparent insulating layer 330 in FIG. 3B is same as the method of forming the first transparent insulating layer 130 in FIG. 1B. There is no need to give unnecessary details.

The first opaque insulating layer 360 covers the top surface 312 of the second region 318 of the transparent substrate 310 and next to the first transparent insulating layer 330. According to embodiments of the disclosure, the material of the first opaque insulating layer 360 is epoxy acrylate resin or acrylic acid. According to embodiments of the disclosure, the thickness of the first opaque insulating layer 360 is same as the first transparent insulating layer 330.

In one embodiment of the disclosure, the method of forming the first opaque insulating layer 360 in FIG. 3B is same as the method of forming the first transparent insulating layer 330. There is no need to give unnecessary details.

The second metal mesh structure 340 is disposed on the bottom surface 314 of the first region 316 of the transparent substrate 310. According to embodiments of the disclosure, the materials and thickness of second metal mesh structure 340 are same as the second metal mesh structure 140 in FIG. 1B.

According to embodiments of the disclosure, the method of forming the second metal mesh structure 340 in FIG. 3B is same as the method of forming the second metal mesh structure 140 in FIG. 1B. There is no need to give unnecessary details.

The second transparent insulating layer 350 surrounds the second metal mesh structure 340 and covers the bottom surface 314 of the first region 316 of the transparent substrate 310. According to embodiment of the disclosure, the materials and thickness of second transparent insulating layer 350 are same as the second transparent insulating layer 150 in FIG. 1B. In one embodiment of the disclosure, the method of forming the second transparent insulating layer 350 in FIG. 3B is same as the method of forming the transparent insulating layer 150 in FIG. 1B. There is no need to give unnecessary details.

The second opaque insulating layer 370 covers the bottom surface 314 of the second region 318 of the transparent substrate 310 and next to the second transparent insulating layer 350. According to embodiments of the disclosure, the material of the second opaque insulating layer 370 is epoxy acrylate resin or acrylic acid. According to embodiments of the disclosure, the thickness of the second opaque insulating layer 370 is same as the second transparent insulating layer 350.

In one embodiment of the disclosure, the method of forming the second opaque insulating layer 370 in FIG. 3B is same as the method of forming the second transparent insulating layer 350. There is no need to give unnecessary details.

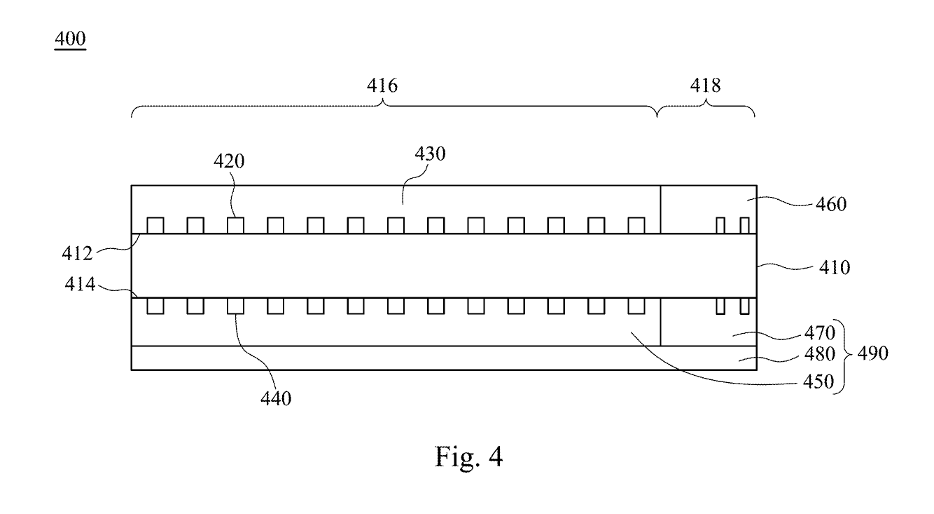

FIG. 4 schematically shows a cross-sectional view of a transparent conductive structure 400 according to the embodiments of the present disclosure. In FIG. 4, the transparent conductive structure 400 includes a transparent substrate 410, a first metal mesh structure 420, a first transparent insulating layer 430, a second metal mesh structure 440, a second transparent insulating layer 450, a first opaque insulating layer 460, a second opaque insulating layer 470 and a transparent protective layer 480.

The transparent substrate 410 has a top surface 412 and a bottom surface 414 opposite to the top surface 412. The transparent substrate 410 has a first region 416 and a second region 418 next to the first region 416. The first metal mesh structure 420 mainly positions on the top surface 412 of the first region 416 of transparent substrate 410. The second metal mesh structure 440 mainly positions on the bottom surface 414 of the first region 416 of transparent substrate 410.

According to embodiments of the disclosure, the materials and thickness of transparent substrate 410 are same as transparent substrate 110 in FIG. 1B.

The first metal mesh structure 420 is disposed on the top surface 412 of the first region 416 of the transparent substrate 410. According to embodiments of the disclosure, the materials and thickness of first metal mesh structure 420 are same as first metal mesh structure 120 in FIG. 1B.

According to embodiments of the disclosure, the method of forming the first metal mesh structure 420 in FIG. 4 is same as the method of forming the first metal mesh structure 120 in FIG. 1B. There is no need to give unnecessary details.

The first transparent insulating layer 430 surrounds the first metal mesh structure 420 and covers the top surface 412 of the first region 416 of the transparent substrate 410. According to embodiment of the disclosure, the materials and thickness of first transparent insulating layer 430 are same as the first transparent insulating layer 130 in FIG. 1B. In one embodiment of the disclosure, the method of forming the first transparent insulating layer 430 in FIG. 4 is same as the method of forming the first transparent insulating layer 130 in FIG. 1B. There is no need to give unnecessary details.

The first opaque insulating layer 460 covers the top surface 412 of the second region 418 of the transparent substrate 410 and next to the first transparent insulating layer 430. According to embodiments of the disclosure, the materials and thickness of the first opaque insulating layer 460 are same as the first opaque insulating layer 360 in FIG. 3B.

In one embodiment of the disclosure, the method of forming the first opaque insulating layer 460 in FIG. 4 is same as the method of forming the first transparent insulating layer 430. There is no need to give unnecessary details.

The second metal mesh structure 440 is disposed on the bottom surface 414 of the first region 416 of the transparent substrate 410. According to embodiments of the disclosure, the materials and thickness of second metal mesh structure 440 are same as the second metal mesh structure 140 in FIG. 1B.

According to embodiments of the disclosure, the method of forming the second metal mesh structure 440 in FIG. 4 is same as the method of forming the second metal mesh structure 140 in FIG. 1B. There is no need to give unnecessary details.

The second transparent insulating layer 450 surrounds the second metal mesh structure 440 and covers the bottom surface 414 of the first region 416 of the transparent substrate 410. According to embodiment of the disclosure, the materials and thickness of second transparent insulating layer 450 are same as the second transparent insulating layer 150 in FIG. 1B. According to embodiments of the disclosure, the method of forming the second transparent insulating layer 450 in FIG. 4 is same as the method of forming the transparent insulating layer 150 in FIG. 1B. There is no need to give unnecessary details.

The second opaque insulating layer 470 covers the bottom surface 414 of the second region 418 of the transparent substrate 410 and next to the second transparent insulating layer 450. According to embodiments of the disclosure, the materials and thickness of second opaque insulating layer 470 are same as the second opaque insulating layer 370 in FIG. 3B. In one embodiment of the disclosure, the method of forming the second opaque insulating layer 470 in FIG. 4 is same as the method of forming the second transparent insulating layer 450. There is no need to give unnecessary details.

The transparent protective layer 480 covers the second transparent insulating layer 450 and the second opaque insulating layer 470. In one embodiment of the disclosure, the second transparent insulating layer 450, the second opaque insulating layer 470 and the transparent protective layer 480 constitute an anti-scattering film 490. According to embodiments of the disclosure, the materials and thickness of transparent protective layer 480 are same as the transparent protective layer 260 in FIG. 2.

In order to solve the phenomenon of Ag ionic migration caused by the method of forming the traditional transparent conductive structure. The embodiments of present disclosure provide a transparent conductive structure having a transparent insulating layer surrounding the metal mesh structures. The surrounding water may be isolated from the transparent conductive structure so that the water avoids contact with the metal mesh structures. By the waterproof and insulating property of transparent insulating layer, the surrounding water cannot permeate or penetrate through the transparent insulating layer and cannot react with the metal mesh structures to generate Ag ionic migration.

On the other hand, because the transparent insulating layer is made of macromolecules, the transparent insulating layer and second transparent insulating layer can constitute a anti-scattering film and increase the safety of the transparent conductive structure.

The embodiments were chosen and described in order to explain the principles of the invention and their practical application so as to activate others skilled in the art to utilize the invention and various embodiments and with various modifications as are suited to the particular use contemplated. Alternative embodiments will become apparent to those skilled in the art to which the present invention pertains without departing from its spirit and scope. Accordingly, the scope of the present invention is defined by the appended claims rather than the foregoing description and the exemplary embodiments described therein.

What is claimed is:

1. A transparent conductive structure having metal mesh, comprising:
a transparent substrate having a top surface and a bottom surface opposite to the top surface;
a first metal mesh structure disposed on the top surface of the transparent substrate;
a first transparent insulating layer surrounding the first metal mesh structure and covering the top surface of the transparent substrate;
a second metal mesh structure disposed on the bottom surface of the transparent substrate; and
a second transparent insulating layer surrounding the second metal mesh structure and covering the bottom surface of the transparent substrate.

2. The transparent conductive structure of claim 1, wherein a material of the first transparent insulating layer, the second transparent insulating layer or a combination thereof is an optical clear adhesive.

3. The transparent conductive structure of claim 1, wherein a thickness of the first transparent insulating layer and the second transparent insulating layer individually are 50-300 μm.

4. The transparent conductive structure of claim 1, wherein a thickness of the first metal mesh structure and the second metal mesh structure individually are 0.8-1.2 μm.

5. The transparent conductive structure of claim 1, further comprising a first anti-scattering film surrounding the second metal mesh structure and covering the bottom surface of the transparent substrate.

6. The transparent conductive structure of claim 5, wherein the first anti-scattering film comprises the second transparent insulating layer and a first transparent protective layer, and the first transparent protective layer covers the second transparent insulating layer.

7. The transparent conductive structure of claim 1, wherein the first transparent insulating layer surrounds the first metal mesh structure and covers the top surface of a first region of the transparent substrate; and the second transparent insulating layer surrounds the second metal mesh structure and covers the bottom surface of the first region of the transparent substrate

8. The transparent conductive structure of claim 7, further comprising a first opaque insulating layer and a second opaque insulating layer, the first opaque insulating layer covering the top surface of a second region of the transparent substrate and next to the first transparent insulating layer; and the second opaque insulating layer covering the bottom surface of the second region of the transparent substrate and next to the second transparent insulating layer

9. The transparent conductive structure of claim 7, further comprising a second anti-scattering film surrounding the second metal mesh structure and covering the bottom surface of the transparent substrate.

10. The transparent conductive structure of claim 9, wherein the second anti-scattering film comprises the second transparent insulating layer, the second insulating layer and a second transparent protective layer, and the second transparent protective layer covers the second transparent insulating layer and the second insulating layer.
